(19) United States
(12) Patent Application Publication
(10) Pub. No.: US 2017/0213907 A1
(43) Pub. Date: Jul. 27, 2017

(54) SWITCHING DEVICE

(71) Applicants: TOYOTA JIDOSHA KABUSHIKI KAISHA, Toyota-shi, Aichi-ken (JP); DENSO CORPORATION, Kariya-shi, Aichi-ken (JP)

(72) Inventors: Akitaka SOENO, Toyota-shi (JP); Sachiko AOI, Nagakute-shi (JP); Shinichiro MIYAHARA, Nagoya-shi (JP)

(73) Assignees: TOYOTA JIDOSHA KABUSHIKI KAISHA, Toyota-shi, Aichi-ken (JP); DENSO CORPORATION, Kariya-shi, Aichi-ken (JP)

(21) Appl. No.: 15/313,448

(22) PCT Filed: Jun. 3, 2015
(86) PCT No.: PCT/JP2015/066113

§ 371 Date: Nov. 22, 2016

(30) Foreign Application Priority Data
Jul. 18, 2014 (JP) 2014-147459

(51) Int. Cl. H01L 29/78; H01L 29/16; H01L 29/66; H01L 29/10

(52) U.S. Cl. CPC H01L 29/7813; H01L 29/1095; H01L 29/1608; H01L 29/66068

(57) ABSTRACT

High voltage-resistance of a switching device including a p-type region being in contact with a lower end of a bottom-insulating-layer is realized. The switching device includes a bottom-insulating-layer disposed at a bottom in a trench, and a gate electrode disposed on a front surface side of the bottom-insulating-layer. A semiconductor substrate includes a first n-type and p-type regions being in contact with the gate insulating film, a second p-type region being in contact with an end of the bottom-insulating-layer, and a second n-type region separating the second p-type region from the first p-type region. Distance A from a rear-surface-side-end of the first p-type region to a front-surface-side-end of the second p-type region, and distance B from a rear-surface-side-end of the-bottom-insulating layer to a rear-surface-side-end of the second p-type region satisfy A<4B.

### TECHNICAL FIELD

### Cross-Reference to Related Application

This application is a related application of Japanese Patent Application No. 2014-147459 filed on Jul. 18, 2014 and claims priority to this Japanese Patent Application, the entire contents of which are hereby incorporated by reference into the present application.

The art disclosed herein relates to a switching device.

### BACKGROUND ART

Japanese Patent Application Publication No. 2005-142243 (hereinbelow referred to as Patent Literature 1) discloses a MOSFET having trench-type gate electrodes. A bottom insulating layer is provided under a gate electrode in each trench. Further, a p-type floating region is provided at a position being in contact with a lower end of each bottom insulating layer. The floating regions are separated from a p-type body region by an n-type drift region. When the MOSFET is turned off, depletion layers extend respectively from both of the body region and the floating regions to the drift region located between the body region and the floating regions. Due to this, the drift region between the body region and the floating regions is depleted, and thus an electric field to be applied to gate insulating films is moderated. Accordingly, a high voltage-resistance is realized in the MOSFET.

### SUMMARY OF INVENTION

### Technical Problem

The aforementioned floating regions are formed by implanting p-type impurities into a bottom surface of each of the trenches, and then diffusing the p-type impurities. If a diffusion distance of p-type impurities is long, a floating region extending upward than a lower end of a bottom insulating layer (that is, lower end of the trench) can be formed as in Patent Literature 1. However, depending on materials of a semiconductor substrate and/or the p-type impurities, there may be a case where the p-type impurities are difficult to diffuse in the semiconductor substrate, and hence the diffusion distance of the p-type impurities becomes short. If the diffusion distance of the p-type impurities is short, a portion of the floating region which extends upward than the lower end of the bottom insulating layer (hereinbelow referred to as upper side portion) becomes small. If the upper side portion is short, an interval between the body region and the floating region becomes wider. Further, if the upper side portion is short, the depletion layer becomes less easy to extend upward from the floating region. Due to this, if the upper side portion is short, the drift region between the body region and the floating region becomes less easy to be depleted, and thus the voltage-resistance property of the MOSFET is deteriorated. Notably, this problem may occur in a case where a p-type region being in contact with the lower end of the bottom insulating layer is not the floating region but a region fixed to a predetermined potential. Thus, the present specification provides an art in which a high voltage-resistance property is realized in a switching device comprising a p-type region at a lower end of a trench, even if an upper side portion of the p-type region is short.

### Solution to Technical Problem

The art disclosed herein is a switching device comprising a semiconductor substrate comprising a front surface and a rear surface, a trench being provided in the front surface; a bottom insulating layer disposed at a bottom portion in the trench; a gate insulating film covering a lateral surface of the trench disposed on a front surface side of the bottom insulating layer; and a gate electrode disposed in the trench and on the front surface side of the bottom insulating layer. The gate electrode is insulated from the semiconductor substrate by the bottom insulating layer and the gate insulating film. The semiconductor substrate comprises: a first n-type region being in contact with the gate insulating film; a first p-type region being in contact with the gate insulating film on a rear surface side of the first n-type region; a second p-type region being in contact with a rear surface side end of the bottom insulating layer; and a second n-type region disposed on the rear surface side of the first p-type region, separated from the first n-type region by the first p-type region, being in contact with the gate insulating film and the bottom insulating layer, extending to a position closer to the rear surface than the second p-type region, and separating the second p-type region from the first p-type region. A distance A which is a distance from a rear surface side end of the first p-type region to an front surface side end of the second p-type region, and a distance B which is a distance from the rear surface side end of the bottom insulating layer to an rear surface side end of the second p-type region satisfy A<4B. A distance C which is a distance from the front surface side end of the second p-type region to the rear surface side end of the bottom insulating layer is shorter than a distance D which is a distance from the rear surface side end of the first p-type region to an rear surface side end of the gate electrode.

Notably, each of the distances A, B, C, and D means a distance measured along a thickness direction of the semiconductor substrate.

In this switching device, an electric field applied to the gate insulating film is suppressed by extending a depletion layer from each of the first p-type region and the second p-type region to the second n-type region located between the first p-type region and the second p-type region (that is, a part of the second n-type region within the distance A). In this switching device, the distance C is smaller than the distance D. When the distance C is small, the depletion layer less easily extends from the second p-type region to a first p-type region side compared to when the distance C is large. However, in this switching device, the distance B is set long (that is, A<4B is satisfied), as a result of which the depletion layer is facilitated to extend from the second p-type region to the first p-type region side. Thus, even when the distance C is small, the depletion layer can be widely extended from the second p-type region to the first p-type region side. Notably, the distance D can be adjusted by an implantation depth of impurities into a bottom surface of the trench, and thus the distance D can be made long even when the p-type impurities are difficult to diffuse in the semiconductor substrate. When the relationship A<4B is satisfied, a high voltage-resistance property can be obtained. Accordingly, this switching device has a high voltage-resistance property.

### BRIEF DESCRIPTION OF DRAWINGS

FIG. 1 is a vertical cross-sectional view of a MOSFET 10,

FIG. 2 is a graph showing a potential distribution in a region along a line Y in FIG. 1 when the MOSFET is off,

FIG. 3 is a graph showing a relationship between a distance A and a second peak P2,

FIG. 4 is a vertical cross-sectional view showing a manufacturing step of the MOSFET 10, and

FIG. 5 is a vertical cross-sectional view showing the manufacturing step of the MOSFET 10.

### DESCRIPTION OF EMBODIMENTS

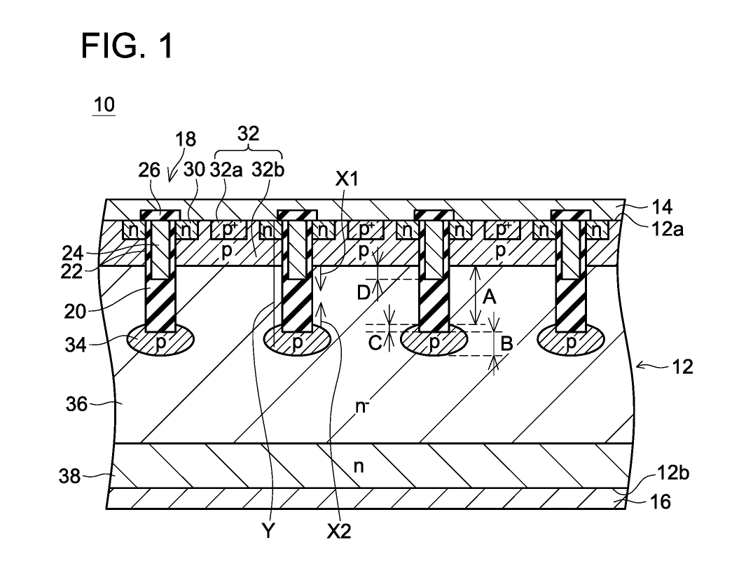

As shown in FIG. 1, a MOSFET 10 of an embodiment comprises a semiconductor substrate 12, a front surface electrode 14, and a rear surface electrode 16. The semiconductor substrate 12 is constituted of SiC. The semiconductor substrate 12 comprises a front surface 12a and a rear surface 12b located on an opposing side of the front surface 12a. The front surface electrode 14 is provided on the front surface 12a. The rear surface electrode 16 is provided on the rear surface 12b.

A plurality of trenches 18 is provided in the front surface 12a of the semiconductor substrate 12. Each trench 18 extends in a direction perpendicular to the front surface 12a (a thickness direction of the semiconductor substrate 12). Further, each trench 18 extends long in a direction perpendicular to a face of paper on which FIG. 1 is illustrated. A bottom insulating layer 20, a gate insulating film 22, and a gate electrode 24 are provided in each trench 18.

Each of the bottom insulating layers 20 is disposed at a bottom portion in its corresponding trench 18. The bottom insulating layers 20 are embedded into the bottom portions of the trenches 18 without a gap.

Each of the gate insulating films 22 covers a lateral surface of its corresponding trench 18, the lateral surface being located upper than (on the front surface 12a side of) the corresponding bottom insulating layer 20.

Each of the gate electrodes 24 is disposed in its corresponding trench 18 upper than the bottom insulating layer 20. That is, each of the bottom insulating layers 20 is disposed between the corresponding gate electrode 24 and the bottom surface of the corresponding trench 18. Further, each of the gate insulating films 22 is disposed between the corresponding gate electrode 24 and the lateral surface of the corresponding trench 18. The gate electrodes 24 are insulated from the semiconductor substrate 12 by the respective bottom insulating layers 20 and the respective gate insulating films 22. An upper surface of each gate electrode 24 is covered by an interlayer insulating film 26. Each gate electrode 24 is insulated from the front surface electrode 14 by the interlayer insulating film 26.

Source regions 30, a body region 32, bottom p-type regions 34, a drift region 36, and a drain region 38 are provided in the semiconductor substrate 12.

The source regions 30 are of an n-type. The source regions 30 are exposed on the front surface 12a of the semiconductor substrate 12. The source regions 30 are electrically connected to the front surface electrode 14. More specifically, the source regions 30 are ohmically connected to the front surface electrode 14. Further, each source region 30 is in contact with the corresponding gate insulating film 22 in a vicinity of the front surface 12a of the semiconductor substrate 12.

The body region 32 is of a p-type. The body region 32 comprises high-concentration body regions 32a and a low-concentration body region 32b.

Each high-concentration body region 32a is provided between the corresponding two source regions 30. The high-concentration body regions 32a are exposed on the front surface 12a of the semiconductor substrate 12. The high-concentration body regions 32a are electrically connected to the front surface electrode 14. More specifically, the high-concentration body regions 32a are ohmically connected to the front surface electrode 14.

A p-type impurity concentration of the low-concentration body region 32b is lower than that of the high-concentration body regions 32a. The low-concentration body region 32b is in contact with the source regions 30 and high-concentration body regions 32a. The low-concentration body region 32b is in contact with the gate insulating films 22 under (on a rear surface 12b side of) the source regions 30. A lower end of the low-concentration body region 32b (that is, a position of an interface between the low-concentration body region 32b and the drift region 36) is located upper than lower ends of the gate electrodes 24.

The drift region 36 is of the n-type. The drift region 36 is provided under the low-concentration body region 32b. The drift region 36 is in contact with the low-concentration body region 32b. The drift region 36 is separated from the source regions 30 by the low-concentration body region 32b. The drift region 36 is in contact with the gate insulating films 22 and the bottom insulating layers 20 under the low-concentration body region 32b. The drift region 36 extends up to a position lower than the bottom p-type regions 34.

Each bottom p-type region 34 is of the p-type and provided so as to be in contact with a bottom surface of the corresponding trench 18. That is, each bottom p-type region 34 is in contact with a lower end of the corresponding bottom insulating layer 20. An upper end of each bottom p-type region 34 is located upper than the lower end of the corresponding bottom insulating layer 20. A part of each bottom p-type region 34 on the upper side is in contact with a lateral surface of the corresponding bottom insulating layer 20. Peripheries of the respective bottom p-type regions 34 are surrounded by the drift region 36. The bottom p-type regions 34 are separated from the low-concentration body region 32b by the drift region 36. Further, each bottom p-type region 34 is separated from other bottom p-type regions 34 by the drift region 36. Each bottom p-type region 34 is in contact with only the corresponding bottom insulating layer 20 and the drift region 36. Thus, a potential of the bottom p-type regions 34 is floating.

The drain region 38 is of the n-type. An n-type impurity concentration of the drain region 38 is higher than that of the drift region 36. The drain region 38 is provided under the drift region 36. The drain region 38 is in contact with the drift region 36. The drain region 38 is exposed on the rear surface 12b of the semiconductor substrate 12. The drain region 38 is electrically connected to the rear surface electrode 16. More specifically, the drain region 38 is ohmically connected to the rear surface electrode 16.

Next, a dimension of each part of the MOSFET 10 will be described. A distance A in FIG. 1 is a distance from the lower end of the low-concentration body region 32b to the upper end of the bottom p-type region 34. A distance B in FIG. 1 is a distance from the lower end of the bottom insulating layer 20 to a lower end of the bottom p-type region 34. The distances A and B are distances measured along the thickness direction of the semiconductor substrate 12. The distance A is shorter than a distance which is four times the distance B. That is, a relationship A<4B is satisfied.

A distance C in FIG. 1 is a distance from the upper end of the bottom p-type region 34 to the lower end of the bottom insulating layer 20. A distance D in FIG. 1 is a distance from the lower end of the low-concentration body region 32b to the lower end of the gate electrode 24. The distances C and D are distances measured along the thickness direction of the semiconductor substrate 12. The distance C is smaller than the distance D. That is, a relationship C<D is satisfied.

Next, an operation of the MOSFET 10 will be described. In an OFF state, a voltage which makes the rear surface electrode 16 have a higher potential is applied between the rear surface electrode 16 and the front surface electrode 14. The voltage applied between the rear surface electrode 16 and the front surface electrode 14 may be, for example, a voltage equal to or higher than 1200V. When a potential of the gate electrodes 24 is raised to or higher than a threshold value in this state, the MOSFET 10 turns into an ON state and the voltage between the rear surface electrode 16 and the front surface electrode 14 drops to a few volts (for example, 3V). That is, when the potential which is equal to or higher than the threshold value is applied to the gate electrodes 24, channels are formed in the low-concentration body region 32b in a range being in contact with the gate insulating films 22. The source regions 30 and the drift region 36 are connected by the channels. Thus, electrons flow from the front surface electrode 14 toward the rear surface electrode 16 through the source regions 30, the channels, the drift region 36, and the drain region 38. Due to this, a current flows from the front surface electrode 14 toward the rear surface electrode 16.

Afterward, when the potential of the gate electrodes 24 is reduced to a potential lower than the threshold value, the channels disappear and the MOSFET 10 turns into the OFF state. When the MOSFET 10 turns into the OFF state from the ON state, a depletion layer extends from the low-concentration body region 32b into the drift region 36. Further, a depletion layer extends from each bottom p-type region 34 into the drift region 36 as well. As above, the drift region 36 is depleted by the depletion layers extending into the drift region 36 from the low-concentration body region 32b and the bottom p-type regions 34. The voltage applied between the rear surface electrode 16 and the front surface electrode 14 (a high voltage) is maintained by the depleted drift region 36.

The drift region 36 located between the low-concentration body region 32b and each bottom p-type region 34 (that is, a part of the drift region 36 shown by the distance A, hereinbelow referred to as interval portion drift region) is depleted from its both sides by the depletion layer extending from the low-concentration body region 32b as shown by an arrow X1 in FIG. 1 and the depletion layer extending from each bottom p-type region 34 as shown by an arrow X2 in FIG. 1. When the depletion layers shown by the arrows X1 and X2 are connected to each other, an entirety of the interval portion drift region is depleted. When the interval portion drift region is depleted, it is considered that an electric field applied to the gate insulating films 22 can be effectively moderated.

In the MOSFET 10 of the present embodiment, the distance C (that is, a thickness of each bottom p-type region 34 protruding upward than the lower end of the corresponding bottom insulating layer 20) is small. When the distance C is small, the distance A becomes long. Further, when the distance C is small, the depletion layer shown by the arrow X2 less easily extends compared to when the distance C is large. Due to this, if the distance C is small, it is disadvantageous when the interval portion drift region is depleted. Meanwhile, the distance B also affects the extension of the depletion layer shown by the arrow X2 as well. That is, when the distance B is large, the depletion layer shown by the arrow X2 more easily extends compared to when the distance B is small. Although the distance C is small in the MOSFET 10 of the present embodiment, the extension of the depletion layer shown by the arrow X2 is facilitated due to the distance B being large. In a case of the distance C being small, it is considered that whether the entirety of the interval portion drift region is depleted or not is determined depending on a ratio between the distance A and the distance B. That is, it is considered that the entirety of the interval portion drift region can be depleted, even if the distance A is large, as long as the distance B is large as well.

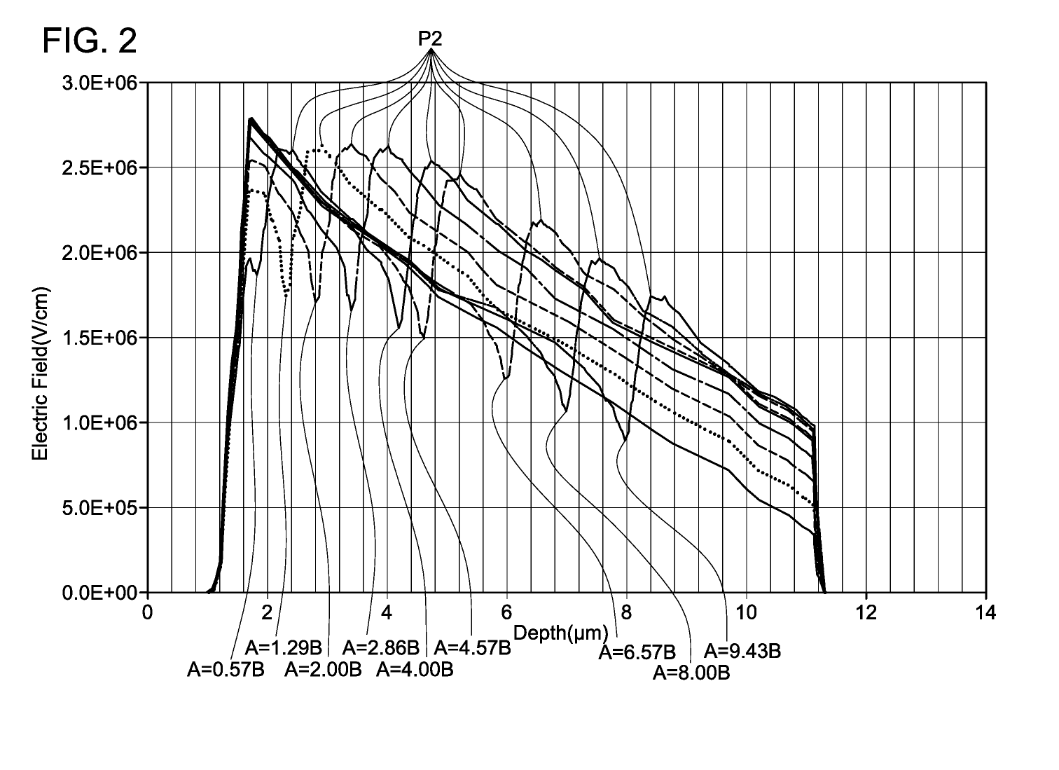

FIG. 2 shows an electrical field distribution in a region along a line Y in FIG. 1 when the MOSFET 10 is off. That is, FIG. 2 shows an electrical field distribution within the source region 30, the body region 32, the drift region 36, and the bottom p-type region 34 in a vicinity of the trench 18 in the thickness direction of the semiconductor substrate 12. A horizontal axis of FIG. 2 represents a depth from the front surface 12a of the semiconductor substrate 12 (that is, a position in the thickness direction of the semiconductor substrate 12) and its left side represents the front surface 12a side. Graphs shown in FIG. 2 were calculated by simulations. FIG. 2 shows electrical field distribution graphs in respective cases where the distance B is fixed and the distance A is varied.

As is clear from FIG. 2, every graph has its first peak at a depth of approximately 1.6 μm. The depth of approximately 1.6 μm is a position of the interface between the low-concentration body region 32b and the drift region 36. Further, every graph has its second peak at a position deeper than its first peak. The position of each second peak P2 is a position of an interface between the bottom p-type region 34 and the drift region 36 located above it. Since the distance A is different in each graph, the larger the distance A is, the deeper the position of the second peak P2 becomes. Further, intensities of the second peaks P2 are substantially constant in cases where the distance A is smaller than 4.00B. This is considered because in the case where A<4B is satisfied, the depletion layers shown by the arrows X1 and X2 in FIG. 1 are connected, and thus the entirety of the interval portion drift region is depleted. Contrary to this, in cases where the distance A is equal to or larger than 4.00B, the larger the distance A is, the smaller the second peak P2 becomes. This is considered because in the case of A≧4B, the depletion layers shown by the arrows X1 and X2 in FIG. 1 are not connected, and thus a gap (a region which is not depleted) remains between the depletion layers shown by the arrows X1 and X2. Since the larger the distance A is, the wider the gap becomes, the electric field that can be maintained by the depletion layer extending from each bottom p-type region 34 reduces. Due to this, in the case of A≧4B, it is considered that the larger the distance A is, the smaller the second peak P2 becomes. In the case of A≧4B, it is considered that not the entirety of the interval portion drift region can be depleted, and thus a high electric field is likely to be applied to the gate insulating films 22. As above, it is considered that the electric field applied to the gate insulating films 22 can be efficiently moderated, if A<4B is satisfied.

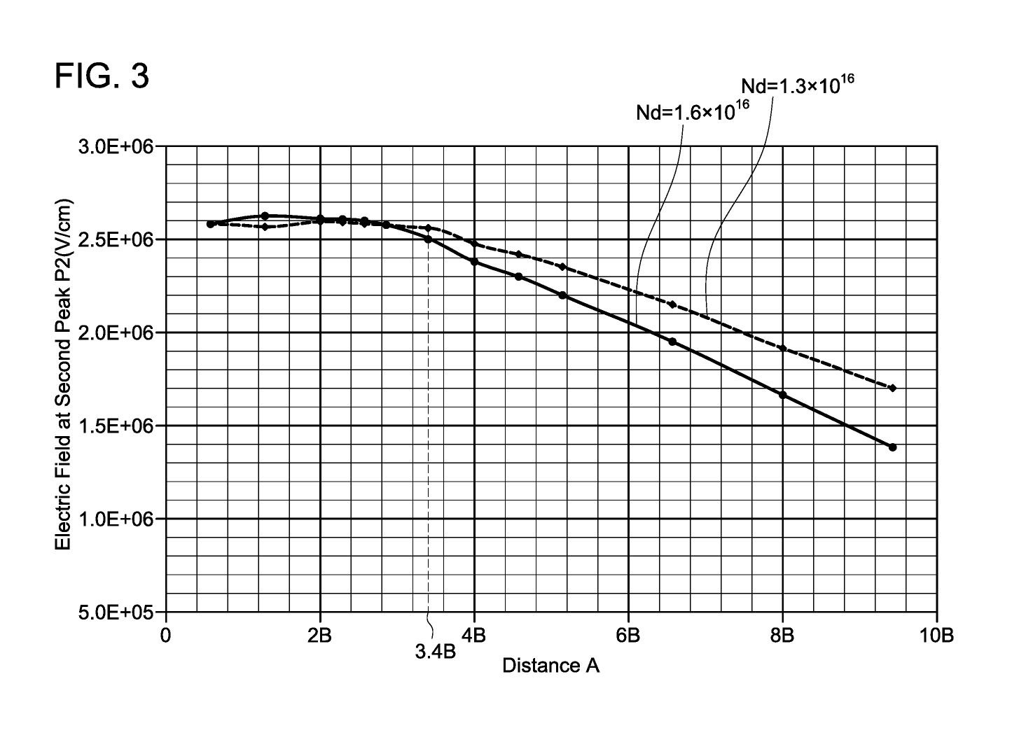

FIG. 3 shows a relationship between the distance A and the electric field at each second peak P2. Notably, FIG. 3 shows respective cases where the n-type impurity concentration Nd of the drift region 36 is 1.3×10¹⁶ atoms/cm³ and the n-type impurity concentration Nd of the drift region 36 is 1.6×10¹⁶ atoms/cm³. In both of the cases, in the case where A<4B is satisfied, the second peaks P2 are substantially constant and it is considered that the entirety of the interval portion drift region 36 can be depleted. Notably, since the depletion layers tend to extend more easily with a lower n-type impurity concentration in the drift region 36, it is more preferable that the n-type impurity concentration of the drift region 36 is equal to or less than 1.6×10¹⁶ atoms/cm³. Further, a variation range of the second peak P2 becomes smaller if A<3.4B, and thus A<3.4B is more preferable.

Notably, a p-type impurity concentration of the bottom p-type regions 34 is set at a concentration with which not entireties of the bottom p-type regions 34 are depleted when the MOSFET 10 is turned off. If the p-type impurity concentration of the bottom p-type regions 34 is set as such, the p-type impurity concentration of the bottom p-type regions 34 does not affect a width by which the depletion layers extend. Due to this, regardless of the p-type impurity concentration of the bottom p-type regions 34, the results of FIGS. 2 and 3 can be obtained. For example, if the p-type impurity concentration of the bottom p-type regions 34 is set equal to or more than 1×10¹⁸ atoms/cm³, not the entireties of the bottom p-type regions 34 are depleted.

As described above, since A<4B is satisfied in the MOSFET 10 of the present embodiment, the entireties of the interval portion drift regions can be depleted when the MOSFET 10 is turned off. Thus, the electric field applied to the gate insulation films 22 is moderated. Due to this, the MOSFET 10 has a high voltage-resistance property.

Next, a manufacturing method of the MOSFET 10 will be described. Notably, the manufacturing method of the MOSFET 10 has features in a step of forming the bottom p-type regions 34, and thus explanations of the other steps will be omitted.

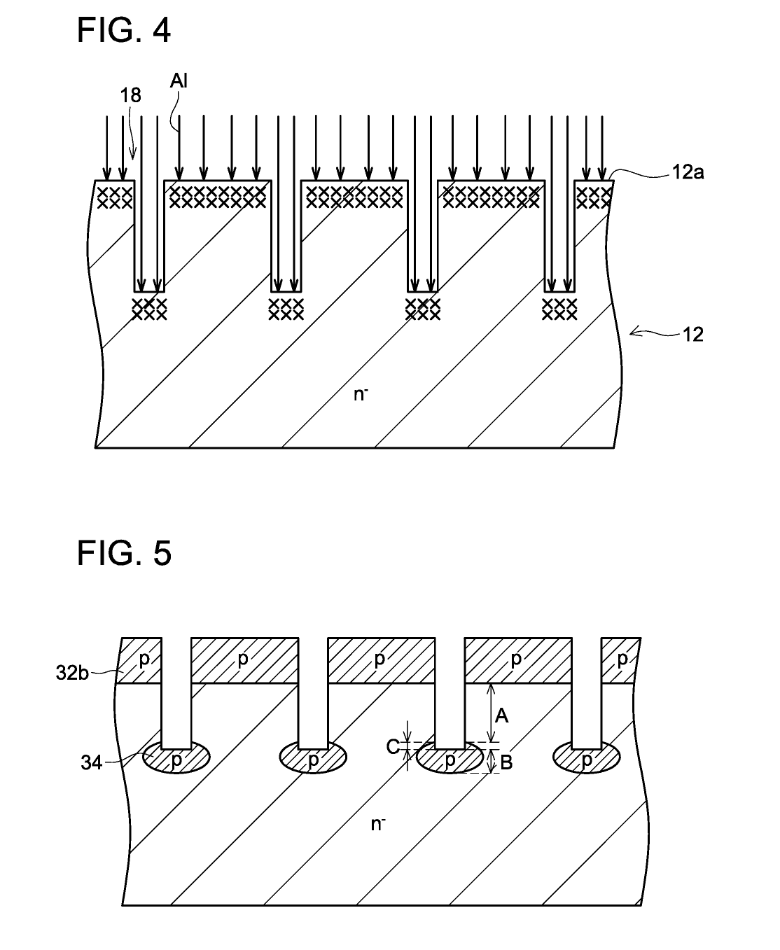

Firstly, the trenches 18 are formed in the front surface 12a of the n-type semiconductor substrate 12 constituted of SIC. Next, as shown in FIG. 4, aluminum (Al) is implanted into the bottom surfaces of the trenches 18. At this occasion, the Al is implanted into the front surface 12a of the semiconductor substrate 12 as well. Next, the semiconductor substrate 12 is subjected to heat treatment, as a result of which the Al implanted into the semiconductor substrate 12 is diffused as well as activated. Due to this, as shown in FIG. 5, the bottom p-type regions 34 are formed in vicinities of the bottom surfaces of the trenches 18. Further, the low-concentration body region 32b is formed in the vicinity of the front surface 12a of the semiconductor substrate 12.

A diffusion coefficient of Al in SiC is extremely small. Thus, a distance by which the Al implanted into the bottom surfaces of the trenches 18 diffuses during the heat treatment after the implantation is short. Due to this, when the bottom p-type regions 34 are formed in the aforementioned method, the distance C becomes short. Since the diffusion distance of the Al becomes slightly longer by increasing an implantation amount of the Al into the bottom surfaces of the trenches 18, it is possible to make the distance C slightly longer. However, in this case, the p-type impurity concentration of the low-concentration body region 32b becomes high, and thus problems such as an increase in a gate threshold potential of the MOSFET 10, an increase in a leak current, and the like may occur. Thus, practically, it is difficult to make the distance C long, and the distance C becomes shorter than the distance D (see FIG. 1).

On the other hand, the distance B can be controlled by an implantation depth upon implanting the Al into the bottom surfaces of the trenches 18. That is, by adjusting an energy at a time of the ion implantation, the Al can be distributed over a wide range between the bottom surface of each trenche 18 to a deep position as shown in FIG. 4. If the Al is distributed to the deep position by the ion implantation as such, even if the diffusion distance of the Al is short during the heat treatment after the ion implantation, the distance B of each bottom p-type region 34 can be made long. Thus, the bottom p-type regions 34 which satisfy A<4B can be formed.

Therefore, according to this method, the MOSFET 10 having a high voltage-resistance property can be manufactured.

Notably, the bottom p-type regions 34 and the low-concentration body region 32b are formed simultaneously in the aforementioned manufacturing method, however, these regions may be formed in separate steps.

Further, the potential of the bottom p-type regions 34 is floating in the MOSFET 10 of the aforementioned embodiment, however, the bottom p-type regions 34 may be connected to a predetermined fixed potential.

Notably, the source regions of the embodiment are an example of a first n-type region of the claims, the body region of the embodiment is an example of a first p-type region of the claims, the bottom p-type regions of the embodiment are an example of a second p-type region of the claims, and the drift region of the embodiment is an example of a second n-type region of the claims.

Further, the embodiment describes the MOSFET, however, the art disclosed herein may be applied to other switching devices such as an IGBT and the like.

A configuration of the switching device of the aforementioned embodiment can be described as below.

The semiconductor substrate may be constituted of a SiC semiconductor, and the second p-type region may contain Al. As such, even if materials of the semiconductor substrate and p-type impurities are a combination in which a diffusion coefficient of the p-type impurities is small in the semiconductor substrate, a high voltage-resistance property can be realized by a relationship A<4B being satisfied.

An n-type impurity concentration of the second n-type region may be equal to or less than 1.6×10¹⁶ atoms/cm³.

The n-type impurity concentration of the second n-type region may be equal to or more than 1.3×10¹⁶ atoms/cm³.

A front surface electrode is provided on a front surface of the semiconductor substrate, and the first n-type region and the first p-type region are connected to the front surface electrode. A rear surface electrode is provided on a rear surface of the semiconductor substrate, and the second n-type region is connected to the rear surface electrode.

Specific examples of the present invention have been described in detail, however, these are mere exemplary indications and thus do not limit the scope of the claims. The art described in the claims include modifications and variations of the specific examples presented above. Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

1. A switching device, comprising:
a semiconductor substrate comprising a front surface and a rear surface, a trench being provided in the front surface;
a bottom insulating layer disposed at a bottom portion in the trench;
a gate insulating film covering a lateral surface of the trench disposed on a front surface side of the bottom insulating layer; and
a gate electrode disposed in the trench and on the front surface side of the bottom insulating layer, the gate electrode being insulated from the semiconductor substrate by the bottom insulating layer and the gate insulating film,
wherein
the semiconductor substrate comprises:
a first n-type region being in contact with the gate insulating film;
a first p-type region being in contact with the gate insulating film on a rear surface side of the first n-type region;
a second p-type region being in contact with a rear surface side end of the bottom insulating layer; and
a second n-type region disposed on the rear surface side of the first p-type region, separated from the first n-type region by the first p-type region, being in contact with the gate insulating film and the bottom insulating layer, extending to a position closer to the rear surface than the second p-type region, and separating the second p-type region from the first p-type region,
wherein
a distance A which is a distance from a rear surface side end of the first p-type region to a front surface side end of the second p-type region, and a distance B which is a distance from the rear surface side end of the bottom insulating layer to a rear surface side end of the second p-type region satisfy A<4B, and
a distance C which is a distance from the front surface side end of the second p-type region to the rear surface side end of the bottom insulating layer is shorter than a distance D which is a distance from the rear surface side end of the first p-type region to a rear surface side end of the gate electrode.

2. The switching device of claim 1, wherein
the semiconductor substrate is constituted of a SiC semiconductor, and
the second p-type region contains Al.
